(19) United States
(12) Patent Application Publication
(10) Pub. No.: US 2018/0054015 A1
(43) Pub. Date: Feb. 22, 2018

(54) ELECTRICAL CONNECTION INCLUDING A LUBRICANT

(71) Applicant: Embedtek, LLC, Waukesha, WI (US)

(72) Inventors: Dan Paul Aicher, Hartland, WI (US); Ryan John Rethwisch, Elm Grove, WI (US)

(21) Appl. No.: 15/679,414

(22) Filed: Aug. 17, 2017

Related U.S. Application Data
(60) Provisional application No. 62/376,208, filed on Aug. 17, 2016.

(51) Int. Cl. H01R 13/03; G06F 1/18; H05K 1/14; H05K 3/00; C10M 113/12; C10G 50/02

(52) U.S. Cl. CPC H01R 13/03; G06F 1/184; H05K 1/141; H05K 3/366; C10M 113/12; C10G 50/02; H05K 3/0091

(57) ABSTRACT

An electrical system includes a motherboard including a receptacle that provides a first plurality of electrical connectors and an auxiliary card including an extension defining a second plurality of electrical connectors. The extension is fixedly coupled to the receptacle to substantially fix the position of the auxiliary card with respect to the mother board and to electrically connect the first plurality of electrical connections and the second plurality of electrical connections. An electrically-conductive lubricant is disposed between the extension and the receptacle.

### BACKGROUND

The invention relates to stationary electrical connections and particularly to lubricated stationary connections that are subject to extreme operating conditions.

One of the challenges in designing systems used in harsh environments is maintaining quality electrical connections on high speed busses. Vibration and corrosion are primary contributors which can lead to connection failures. In early stages these failures may appear as intermittent communication or undetected devices, requiring removal and reinstallation before normal operation is restored. In more advanced stages, these connections may become worn to the extent that a reseat will no longer resolve the issue and hardware replacement is necessary.

With the growing size and weight of graphics or other auxiliary cards, PCI express connections have been one of the most susceptible connectors to mechanical failure. Significant time has been spent designing and validating mechanical retention mechanisms to support and retain these cards. However, when these large cards are used in a high vibration environments mechanical wear can still occur.

### SUMMARY

In one construction, an electrical system includes a motherboard including a receptacle that provides a first plurality of electrical connectors and an auxiliary card including an extension defining a second plurality of electrical connectors. The extension is fixedly coupled to the receptacle to substantially fix the position of the auxiliary card with respect to the mother board and to electrically connect the first plurality of electrical connections and the second plurality of electrical connections. An electrically-conductive lubricant is disposed between the extension and the receptacle.

In another construction, an electrical system includes a motherboard including a receptacle that includes a slot having a first width, a first plurality of electrical connections disposed within the slot and providing a plurality of electrical connectors between the receptacle and the motherboard, and an auxiliary card including an extension having a second width that is larger than the first width. A second plurality of electrical connectors is coupled to the extension and provides a plurality of electrical connections between the extension and the auxiliary card. The extension is insertable into the receptacle to define an interference fit therebetween to substantially fix the position of the auxiliary card with respect to the motherboard and to electrically connect the auxiliary card and the motherboard. An electrically-conductive lubricant is disposed between the extension and the receptacle.

In yet another construction, the invention provides a method of reducing wear between an auxiliary card and a motherboard. The method includes providing a mother board having a receptacle that defines a slot having a first width, providing an auxiliary card including an extension that defines a second width that is greater than the first width, and applying a lubricant to one of the extension and the slot. The method further includes inserting the extension into the slot to define an interference fit therebetween to substantially fix the position of the auxiliary card with respect to the motherboard and to electrically connect the auxiliary card and the motherboard.

Other aspects of the invention will become apparent by consideration of the detailed description and accompanying drawings.

### BRIEF DESCRIPTION OF THE DRAWINGS

FIG. 1 is a top view of a motherboard including various connectors including several PCI Express connectors;

FIG. 2 is an exploded perspective view of an auxiliary card and a receptacle for receiving the card;

FIG. 3 is an enlarged view of a connector of the card of FIG. 2 after operation without a lubricant; and

FIG. 4 is an enlarged view of a connector of the card of FIG. 2 after operation with a lubricant.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

### DETAILED DESCRIPTION

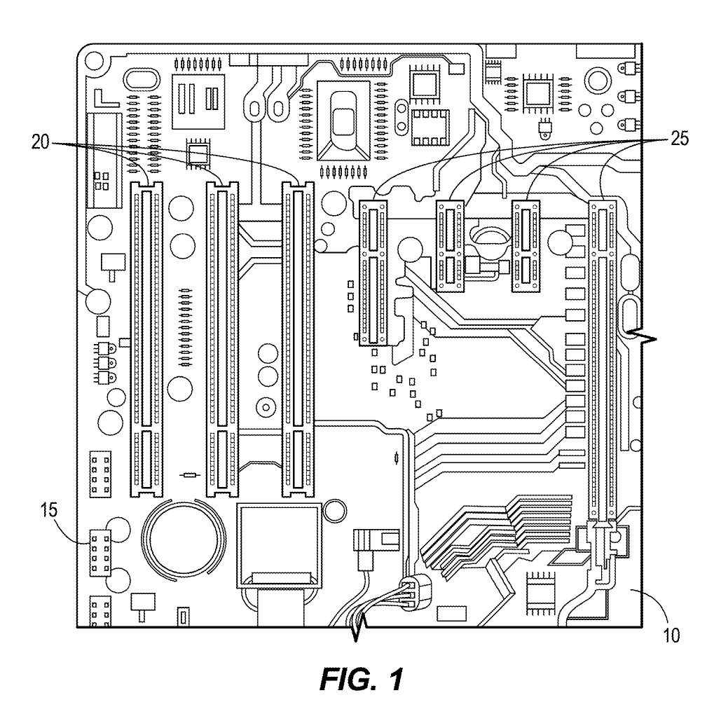

FIG. 1 illustrates a mother board or main board 10 that includes various electrical components 15 (e.g., memory, central processing unit, resistors, capacitors, etc.) and several Peripheral Component Interconnect (PCI) 20 and Peripheral Component Interconnect Express (PCI Express) 25 receptacles arranged to receive auxiliary cards 30 that connect using the PCI or PCI Express standard. As one of ordinary skill in the art will realize, other connector types or standards are possible and could be used with the present invention.

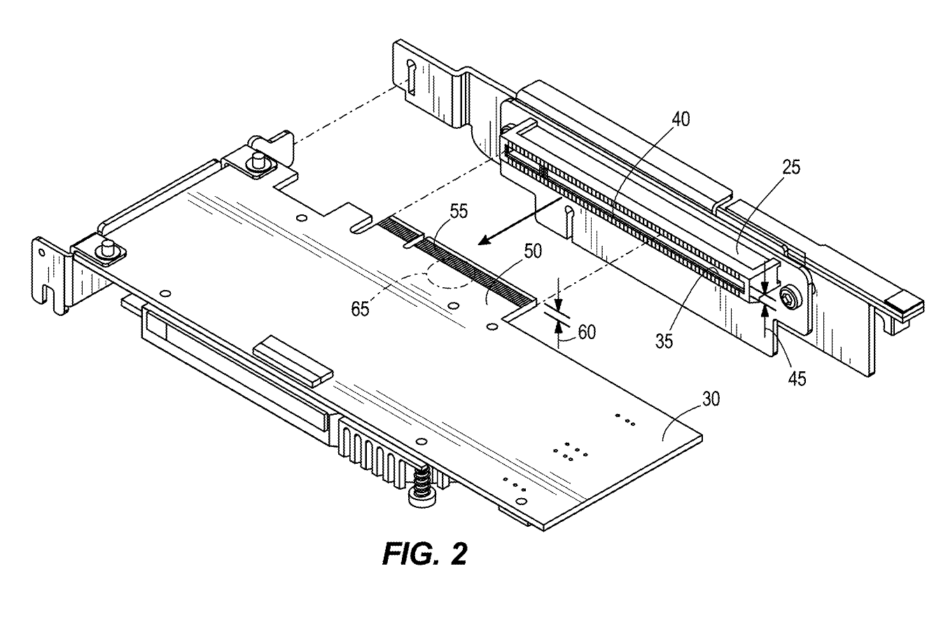

As illustrated in FIG. 2, the PCI Express receptacle 25 includes a slot 35 and a plurality of electrical connectors 40 disposed in the slot 35. The space between electrical connectors 40 across the slot 35 defines a slot width 45. The auxiliary card 30 includes an extension 50 that supports a plurality of electrical connectors 55 permanently affixed to the exterior of the extension 50. The electrical connectors 55 are spaced apart from one another across the extension 50 to define a second width 60. In preferred constructions the second width 60 is greater than the first width 45 to define an interference fit between the auxiliary card 30 and the receptacle 25. Thus, in order to install the auxiliary card 30, the user must apply sufficient force to open the receptacle 25 to slide the extension 50 into the slot 35 of the receptacle. The stiffness and rigidity of the receptacle 25 squeezes the extension 50 to firmly hold the card 30 in place and to provide a good electrical connection between the connectors 40 within the slot 35 and the connectors 55 on the exterior of the extension 50.

A lubricant 65, illustrated in FIG. 2 is placed on the connectors 55 of the extension 50 and/or into the slot 35 of the receptacle 25. The lubricant 65 assists in the installation of the auxiliary card 30 and reduces the likelihood of damage to the connectors 40, 55 during the installation process. In a preferred construction, the lubricant 65 includes a synthetic hydrocarbon grease with more preferred constructions including silica as a thickening agent to assure that the lubricant 65 has the proper consistency for use in the intended operating environment. A preferred lubricant 65 has an operating temperature range between about −40 degrees centigrade and 135 degrees centigrade and a dielectric strength of about 115 Volts/mil (4530 Volts/mm). One suitable lubricant 65 is sold under the name NYOGEL.

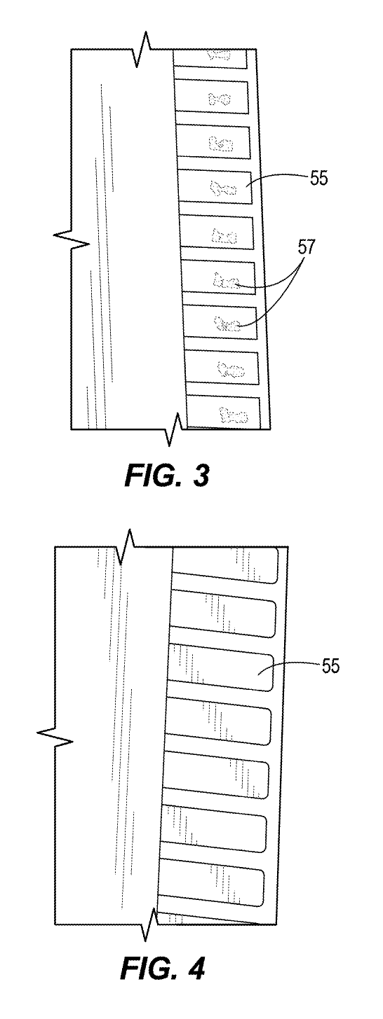

A test was defined to evaluate the impact of the lubricant 65 on a typical PCIe connection. A MIL-STD-810F test was selected to reproduce an environment containing high levels of vibration. The vibration profile parameters were selected from MIL-STD-810F 514.5C-1 and were executed for a duration of four hours. A baseline test was performed using a system without lubrication applied to the connectors 40, 55. After the test was completed the system was powered on and the PCIe device was not detected by the system. After powering the unit off and reseating the card 30, it was able to be detected. The card 30 was then removed from the system, cleaned with electrical contact cleaner and eraser. The contacts 55 used for this test are shown in FIG. 3. The contacts 55 have pitting at the highest compression point 57 of the contacts 55 as well as longer, shallower, wear lines over the length of the contact 55.

A second test was then completed using identical hardware. Prior to installing the PCIe card 30 in the second system the lubricant 65 was applied to the contacts 55 on the card 30. The test was then completed according to the method described above. Upon test completion the unit was powered on and the PCIe card 30 was detected and functioned properly. The card 30 was then removed and the contacts 55 were cleaned with contact cleaner and an eraser. The contacts 55 were pitted similarly to the first test card 30, however there were no visible wear lines on the contacts 55. The image of the contacts 55 are shown in FIG. 4.

To prevent adverse material reactions it is critical to confirm that the lubricant 65 is compatible with the materials used in the contacts 40, 55 and nearby components 15. The following table identifies the common materials used in systems and their compatibility with the selected lubricant 65.

| Component(s) | Material | Material Type | Compatibility |
|---|---|---|---|
| PCB's | AIM SN100C, Lead-free solder material | metal | yes |
| Memory | Aluminum | metal | yes |
| Memory | Borophosphosilicate glass (BPSG) | glass | yes |
| PCB's | Brass | metal | yes |
| PCB's | Ceramic | glass | yes |
| PCB's | Clear Chromate coating | metal | yes |
| PCB's | Copper | metal | yes |
| PCB's | FR4, board material in PCB's | multiple | yes |
| Memory | Glass (Silicon Dioxide) | glass | yes |
| Memory, PCB's | Gold | metal | yes |
| Memory | Lead | metal | yes |
| PCB's | Nickel | metal | yes |
| PCB Connectors | NY6T | plastic | yes |
| PCB Connectors | Nylon 46 | plastic | yes |
| PCB Connectors | Nylon 66 | plastic | yes |
| PCB Connectors | Nylon 67 | plastic | yes |
| PCB Connectors | Nylon 9T | plastic | yes |
| PCB's | PA66 (Glass) | glass | yes |
| PCB's | Phosphor Bronze | metal | yes |
| Memory | Silicon | glass | yes |
| PCB's | Silver | metal | yes |
| PCB's | Stainless Steel | metal | yes |
| PCB Brackets, Chassis Parts | Steel | metal | yes |
| Memory, PCB's | Tin | metal | yes |
| PCB's | Woven Glass | glass | yes |
| PCB Brackets, Chassis Parts | Zinc | metal | yes |

Testing to determine the change on several common parts was then conducted to confirm chemical compatibility findings. The test involved applying the lubricant 65 to several parts while leaving other areas uncoated. The parts were then placed in a thermal chamber at 70 degrees C. for 336 hours. Once removed the parts we placed at room temperature and allowed to cool. The lubricated surfaces were then cleaned with a towel. Multiple durometer measurements were performed on each part. Both lubricated and unlubricated surfaces were measured. The following table shows the impact of the parts:

| | Durometer | Durometer | Durometer | |
|---|---|---|---|---|
| Description | (Untested) | (Tested) | (Tested w/ Nyogel) | % Diff |
| Overmolding Sleeve—Trexprene Black | N/A | 73.75 | 69.75 | −5% |
| SATA cable—Insulation | N/A | 97 | 99 | 2% |
| SATA cable—Connector | N/A | 88.25 | 93 | 5% |
| Serial cable—Insulation | N/A | 94.25 | 93.25 | −1% |
| Serial cable—Connector | N/A | 79.5 | 76.5 | −4% |
| Dual USB Front panel cable—Connector | N/A | 59.5 | 60.5 | 2% |
| Dual USB Front panel cable—Insulation | N/A | 88 | 85.5 | −3% |
| Floppy to SATA Power cable—Insulation | N/A | 87.5 | 86 | −2% |
| Capacitor (C649) | 101.5 | N/A | 101.5 | 0% |
| CMOS Battery | 95.5 | N/A | 96 | 1% |
| RAM DDR3 SODIMM Socket (SODIMM0) | 81 | N/A | 79.75 | −2% |
| PCI Express 1.0a ×1 Housing (PCIe ×1) | 50.5 | N/A | 53 | 5% |
| PCI Express Half-Mini Card Slot (PCIe HMC) | 75.25 | N/A | 71.25 | −5% |
| 3-Wire System Fan Header | 67.5 | N/A | 68 | 1% |
| Audio Line In Connector (Pink) | 85.75 | N/A | 87.5 | 2% |
| Audio Line Out Connector (Green) | 86 | N/A | 84.75 | −1% |
| LVDS Connector | 92.25 | N/A | 93.5 | 1% |
| Internal Power Connector, 2 Pin | 96.5 | N/A | 92.5 | −4% |
| Cap. Package (C353/C354/C373/C374) | 97.5 | N/A | 97.25 | 0% |
| VGA Connector | 60 | N/A | 58.5 | −3% |
| CG82NM10 SLGXX Chip (IC VGA) | 100 | N/A | 100 | 0% |
| SATA Power Connector | 87.5 | N/A | 94.5 | 8% |
| SATA Data Connector (SATA0) | 84 | N/A | 85.25 | 1% |
| SATA Data Connector (SATA1) | 93.75 | N/A | 94.75 | 1% |
| Chip Package (L28) | 96.5 | N/A | 97.5 | 1% |
| PCB | 94.5 | 94.5 | 95.25 | 1% |
| PCI Video Card Slot | N/A | 89.5 | 89.75 | 0% |

Durometer (untested) indicates a measurement taken on a part that was not subjected to the prolonged heat. Durometer (tested) indicates that the part was subjected to the heat prior to making the durometer measurement.

As the table above shows, all parts tested experienced less than a 10 percent change in durometer readings. This small amount of change is further minimized by the additional mechanical retention that is used to support connections with significant mass such as add in cards 30 or large cables.

By applying lubrication 65 to the contacts 40, 55, friction is minimized and contact wear and damage (e.g., installation damage, fretting, oxidation, etc.) is reduced resulting in a significant reliability improvement.

Various features and advantages of the invention are set forth in the following claims.

What is claimed is:

1. An electrical system comprising:
a motherboard including a receptacle that provides a first plurality of electrical connectors;
an auxiliary card including an extension defining a second plurality of electrical connectors, the extension fixedly coupled to the receptacle to substantially fix the position of the auxiliary card with respect to the mother board and to electrically connect the first plurality of electrical connections and the second plurality of electrical connections; and
an electrically-conductive lubricant disposed between the extension and the receptacle.

2. The electrical system of claim 1, wherein the receptacle includes a narrow slot and the first electrical connectors are disposed within the slot to define a slot width.

3. The electrical system of claim 2, wherein the second electrical connectors are permanently coupled to an exterior of the extension to define an extension width that is greater than the slot width.

4. The electrical system of claim 1, wherein the receptacle and the extension are arranged to define a Peripheral Component Interconnect Express (PCI Express) connection.

5. The electrical system of claim 1, wherein the lubricant includes a synthetic hydrocarbon.

6. The electrical system of claim 5, wherein the lubricant includes a silica thickened grease.

7. An electrical system comprising:
a motherboard including a receptacle that includes a slot having a first width;
a first plurality of electrical connections disposed within the slot and providing a plurality of electrical connectors between the receptacle and the motherboard;
an auxiliary card including an extension having a second width that is larger than the first width;
a second plurality of electrical connectors coupled to the extension and providing a plurality of electrical connections between the extension and the auxiliary card, the extension insertable into the receptacle to define an interference fit therebetween to substantially fix the position of the auxiliary card with respect to the motherboard and to electrically connect the auxiliary card and the motherboard; and
an electrically-conductive lubricant disposed between the extension and the receptacle.

8. The electrical system of claim 7, wherein the receptacle and the extension are arranged to define a Peripheral Component Interconnect Express (PCI Express) connection.

9. The electrical system of claim 7, wherein the lubricant includes a synthetic hydrocarbon.

10. The electrical system of claim 9, wherein the lubricant includes a silica thickened grease.

11. A method of reducing wear between an auxiliary card and a motherboard, the method comprising:
providing a mother board having a receptacle that defines a slot having a first width;
providing an auxiliary card including an extension that defines a second width that is greater than the first width;
applying a lubricant to one of the extension and the slot; and
inserting the extension into the slot to define an interference fit therebetween to substantially fix the position of the auxiliary card with respect to the motherboard and to electrically connect the auxiliary card and the motherboard.

12. The method of claim 11, wherein the lubricant includes a synthetic hydrocarbon.

13. The method of claim 11, wherein the lubricant includes a silica thickened grease.
